(19) United States
(12) Patent Application Publication
(10) Pub. No.: US 2014/0299273 A1
(43) Pub. Date: Oct. 9, 2014

(54) MULTI-SEGMENT ELECTRODE ASSEMBLY AND METHODS THEREFOR

(71) Applicant: LAM Research Corporation, Fremont, CA (US)

(72) Inventor: Andreas Fischer, Castro Valley, CA (US)

(73) Assignee: LAM Research Corporation, Fremont, CA (US)

(21) Appl. No.: 13/858,834

(22) Filed: Apr. 8, 2013

(51) Int. Cl. H01J 37/32

(52) U.S. Cl. CPC H01J 37/32091; H01J 37/32082
USPC 156/345.48; 315/111.21

(57) ABSTRACT

A multi-segment electrode assembly having a plurality of electrode segments for modifying a plasma in a plasma processing chamber is disclosed. There is included a first powered electrode segment having a first plasma-facing surface, the first powered electrode segment configured to be powered by a first RE signal. There is also included a second powered electrode segment having a second plasma-facing surface, the second powered electrode segment configured to be powered by a second RE signal. The second powered electrode segment is electrically insulated from the first powered electrode segment, while at least one of the first plasma-facing surface and the second plasma-facing surface is non-planar.

### BACKGROUND OF THE INVENTION

The present invention relates generally to substrate processing technologies. More particularly, embodiments of the invention relate, to methods and apparatuses for processing substrates (e.g., silicon-based wafers or wafers based on other types of material) in a plasma processing chamber.

Generally speaking, the substrate may be processed in a series of steps in which substrate materials are selectively removed (etched) or deposited or otherwise processed. The processed substrate (or dies cut from the processed substrate) ma then be employed to form a variety of electronic devices, such as display panels or integrated circuits for example. Substrate processing technologies in general are well-known and will not be further elaborated here for brevity's sake.

Plasma-enhanced processing is also well-known and has proven to be particularly suitable for forming the extremely small and/or fine features required in modem electronic devices. Plasma etching, for example, employs plasma formed from a process gas (which may be a single gas or a mixture of different gases) to selectively etch material from exposed (e.g., unmasked) areas of the substrate. Various plasma generation technologies have been employed to form the plasma, including for example capacitively coupled plasma veneration, inductively coupled plasma generation, ECR (electron-cyclotron resonance), microwave, author hybrids thereof.

In a typical capacitively coupled plasma (CCP) processing chamber, for example, two or more electrode assemblies may be disposed in a spatially separated manner, with at least one of the electrode assemblies powered by one or more RE generator(s). In an example configuration, two electrode assemblies are employed, with the chuck (substrate support electrode assembly) either grounded or powered by an RF power supply via an RF match. The other electrode assembly (referred herein as the upper electrode assembly) may, for example, be disposed above the chuck in a spaced-apart relationship in order to form a plasma generation region. The plasma generation region may be further defined, in some implementations, by a set of confinement rings to confine the plasma and/or to control rate with which byproduct gases are exhausted from the plasma generation region. The upper electrode assembly may be grounded or may be powered by an RF power source, in some implementations.

To facilitate discussion, FIG. 1 shows a highly simplified drawing of an example capacitively coupled plasma (CCP) processing chamber 102 having a lower electrode/chuck assembly 104, which is powered by an RF power supply 100. A substrate 106 is shown disposed on lower electrode/chuck assembly 104 during substrate processing. An upper electrode assembly 108 is shown disposed above and in a spaced-apart manner from substrate 106, conceptually forming a plasma generation region 110 in which plasma 112 may be formed from injected process gas (not shown to simplify the drawing). In the example of FIG. 1, upper electrode assembly 108 is energized by an RF signal supplied by RF power supply 120.

Optional confinement rings 114 may be provided to confine plasma 112 in plasma generation region 110 as well as to control the pressure within plasma generation region 110. The CCP chamber 102 of FIG. 1 is highly simplified, as mentioned, and variations exist with respect to, for example, the type of chuck employed, the manner with which the process gas is injected, the manner with which pressure is controlled, the number of electrodes, the location of the electrodes, the number and frequencies of the RF power supplies, etc. Irrespective, capacitively coupled plasma processing chambers and their variations are well known. For example, one variation of the above-discussed example may involve using a grounded chuck assembly in cooperation with a powered upper electrode.

Generally speaking, a larger substrate yields a larger number of cut dies. To increase production output (e.g., a greater number of electronic devices manufactured per unit of time), manufacturers strive to employ large substrates whenever possible. As the substrate increases in size, it becomes more challenging to maintain an acceptable level of process result uniformity (e.g., etch rate and/or etch depth). For larger substrates (e.g., 300 mm or above) processed in capacitively coupled plasma process chambers, maintaining a satisfactory level of process uniformity (such as, but not limited to, radial uniformity from the center of the substrate to the edge of the substrate) has proven to be challenging.

To enhance localized control of uniformity, multi-segment upper electrode assemblies have been proposed. in an example multi-segment upper electrode assembly, multiple concentric electrode segments may be provided, with each electrode segment powered by its own RF signal and generally electrically insulated from other electrode segments of the upper electrode assembly. By manipulating the RF signals provided to different electrode segments of the multi-segment upper electrode assembly, a process engineer may be able to exercise some degree of control over local uniformity.

As the critical dimension (CD) of devices shrinks and process result requirements become more exact, manufacturers continue to strive to further improve process uniformity across the substrate surface.

In view of the foregoing, improved methods and apparatus for processing substrates with improved process uniformity in a plasma processing system are desired.

### BRIEF SUMMARY OF THE INVENTION

The invention relates, in an embodiment, to a multi-segment electrode assembly having a plurality of electrode segments for modifying a plasma in a plasma processing chamber. There is included a first powered electrode segment having a first plasma-facing surface, the first powered electrode segment configured to be powered by a first RF signal. There is also included a second powered electrode segment having a second plasma-facing surface, the second powered electrode segment configured to be powered by a second RF signal. The second powered electrode segment is electrically insulated from the first powered electrode segment, while at least one of the first plasma-facing surface and the second plasma-facing surface is non-planar.

In another embodiment, the invention relates to a plasma processing system having at least a plasma processing chamber for processing a substrate. There is included a substrate holder configured for supporting the substrate during the processing. There is also included a multi-segment electrode assembly disposed in a spaced-apart manner opposite the substrate holder, wherein a plasma generating volume exists in to gap between the multi-segment electrode and the substrate during the processing. The multi-segment electrode assembly includes a first powered electrode segment having a first substrate holder-facing surface, the first powered electrode segment configured to be powered by a first RF signal. The multi-segment electrode assembly also includes a second powered electrode segment having a second substrate holder-facing surface, the second powered electrode segment configured to be powered by a second RF signal. The second powered electrode segment is electrically insulated from the first powered electrode segment, while at least one of the first substrate holder-facing surface and the second substrate holder-facing surface is non-planar.

### BRIEF DESCRIPTION OF THE DRAWINGS

The present invention is illustrated by way of example, and not by way of limitation, in the figures of the accompanying drawings and in which like reference numerals refer to similar elements and in which:

To facilitate discussion, FIG. 1 shows a highly simplified drawing of an example capacitively coupled plasma (CCP) processing chamber having a grounded lower electrode/chuck assembly and a powered upper electrode assembly.

FIG. 2A illustrates the mean surface plane for a plasma-facing surface of an electrode segment.

FIG. 2B illustrates three co-planar surfaces.

FIG. 2C illustrates some examples of non co-planar surfaces.

FIG. 3 shows, in accordance with an embodiment of the invention, the cross-section view of a multi-segment electrode having four electrode segments.

FIG. 4 conceptually shows the effect that the plasma-facing surface profile of a given concentric electrode segment has on the etch rate across the wafer.

FIG. 5 shows, in accordance with an embodiment of the invention, the steps for tuning process uniformity using the inventive multi-segment electrode having at least one shaped plasma facing surface for at least one of its electrode segments.

FIG. 6A shows, in accordance with an embodiment, a concentric ring electrode segment having a concave plasma-facing surface.

FIG. 6B shows, in accordance with an embodiment, a concentric ring electrode segment having a convex plasma-facing surface.

### DETAILED DESCRIPTION OF EMBODIMENTS

The present invention will now be described in detail with reference to a few embodiments thereof as illustrated in the accompanying drawings. In the following description numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

Various embodiments are described herein below, including methods and techniques. It should be kept in mind that the invention might also cover articles of manufacture that includes a computer readable medium on which computer-readable instructions for carrying out embodiments of the inventive technique are stored. The computer readable medium may include, for example, semiconductor, magnetic, opto-magnetic, optical, or other forms of computer readable medium for storing computer readable code. Further, the invention may also cover apparatuses for practicing embodiments of the invention. Such apparatus may include circuits, dedicated and/or programmable, to carry out tasks pertaining to embodiments of the invention. Examples of such apparatus include a general-purpose computer and/or a dedicated computing device when appropriately programmed and may include a combination of a computer/computing, device and dedicated/programmable circuits adapted for the various tasks pertaining to embodiments of the invention.

Embodiments of the invention relate to a multi-segment electrode assembly (such as, for example, a multi-segment upper electrode assembly or a multi-segment electrode assembly disposed on the side of the plasma generating region) having a plurality of electrode segments energized by a plurality of RE signals, with at least one of the electrode segments having a plasma-facing surface that is non-planar. The electrode segments are electrically insulated from one another, and the RE signals that power these electrode segments may differ from one another with respect to voltage, current, phase, frequency, and/or other RE signal parameters.

In one or more embodiments, the plasma-facing surface of at least one of the electrode segments of the multi-segment electrode assembly is concave. In one or more embodiments, the plasma-facing surface of at least one of the electrode segments of the multi-segment electrode assembly is convex. In one or more embodiments, the plasma-facing surface of at least one of the electrode segments of the multi-segment electrode assembly is convex while the plasma-facing surface of another electrode segment of the same multi-segment electrode assembly is concave. In one or more embodiments, the plasma-facing surface of at least one of the electrode segments of the multi-segment electrode assembly is convex while the plasma-facing of another electrode segment of the same multi-segment electrode assembly is concave and while the plasma-facing surface of yet another electrode segment of the same multi-segment electrode assembly is planar (i.e., flat).

In one or more embodiments, the plasma-facing surfaces (whether concave, convex, or planar) of the electrode segments of the multi-segment electrode assembly are co-planar with one another. In one or more embodiments, the plasma-facing surfaces (whether concave, convex, or planar) of the electrode segments of the multi-segment electrode assembly are not co-planar, their plasma-facing surfaces form a stepped profile.

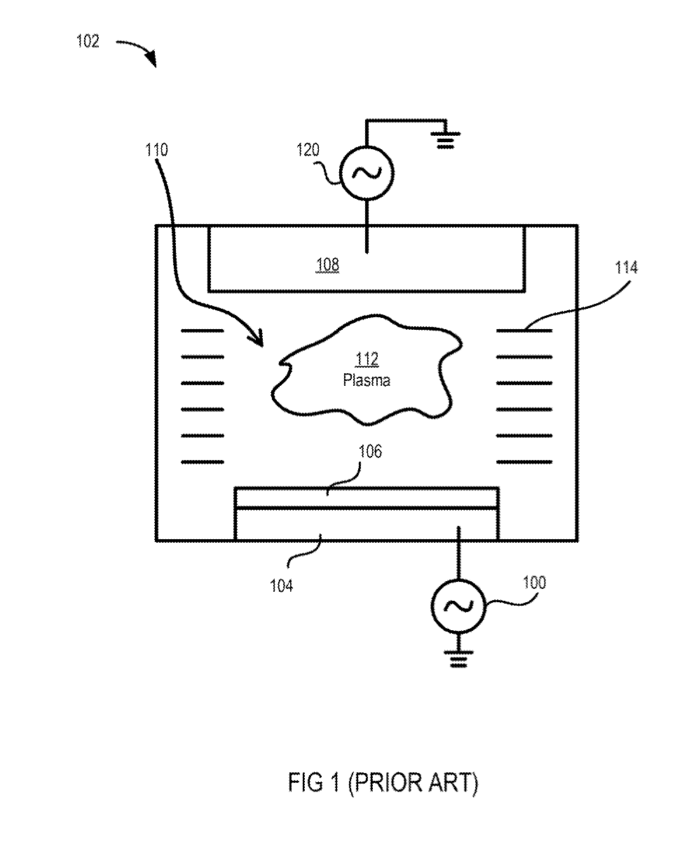

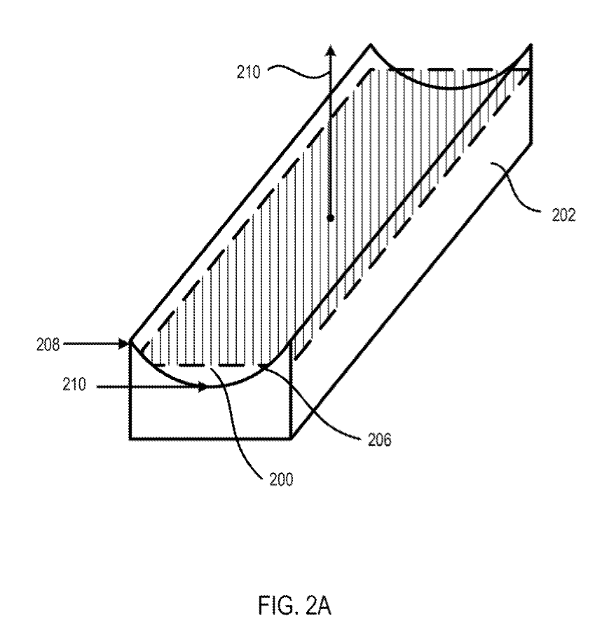

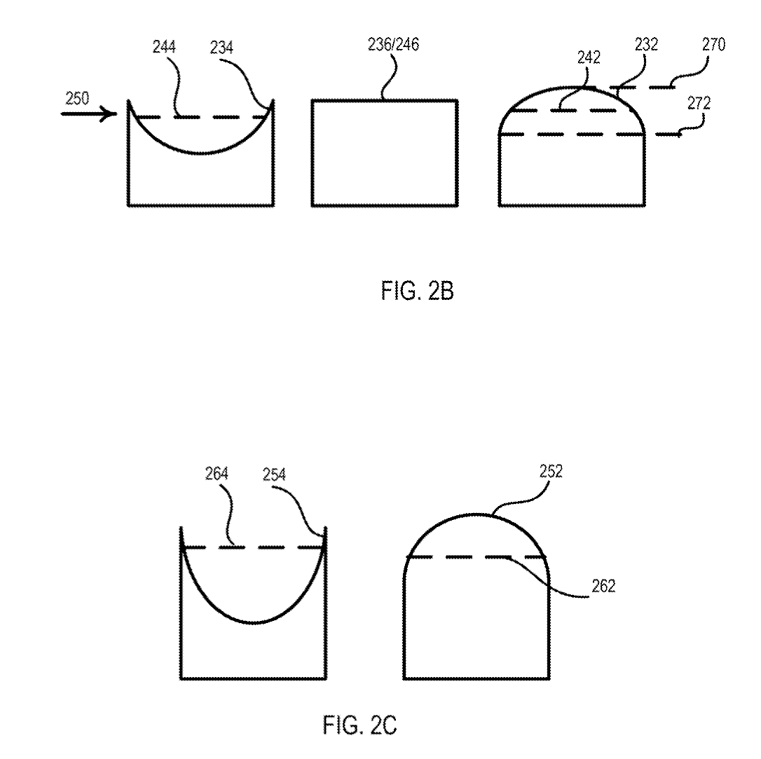

As the term is employed herein, a plasma-facing surface is planar when it is flat. Two surfaces (whether flat or convex or concave) are deemed co-planar when their mean surface planes (defined as the plane that is disposed half way between the surface maxima and minima) exist in the same plane. FIG. 2A illustrates the mean surface plane 200 for plasma-facing surface 206 of an electrode segment 202. Mean surface plane 200 is perpendicular to the normal vector 210 that is normal to the surface 206 of electrode segment 202 and lies half-way between maxima 208 and minima 210 of surface 206. With respect to FIG. 2B, convex surface 232 has a mean surface plane 242 that is also perpendicular to the surface normal vector (not shown) and lies half-way between maxima 270 and minima 272. Convex surface 232, concave surface 234, and flat surface 236 (cut-away end views of three electrode segments in this example) are deemed co-planar because their mean surface planes 242, 211, and 246 exist in the same plane (pointed to by reference arrow 250). With respect to FIG. 2C, for example, convex surface 252 and concave surface 254 (cut-away end views of two electrode segments in this example) are not co-planar since their mean surface planes 262 and 264 do not exist in the same plane.

In one or more embodiments, different degrees of concavity or different degrees of convexity (i.e., different degrees of curvature for the convex and/or concave surfaces) may be employed on plasma-facing surfaces of different electrode segments. In other words, it is not required that all concave plasma-facing surfaces have the same degree of concavity (although such sameness of curvature may be implemented if desired) or all convex plasma-facing surfaces have the same degree of convexity (although such sameness of convex curvature may also be implemented if desired). Further, the concavity or convexity of the non-planar plasma-facing surface may assume any non-planar concave or convex geometric shape, including for example circular (e.g., spherical or part of a sphere), parabolic, elliptical, etc. These surfaces may also be complex surfaces, formed of multi-segments if desired.

In one or more embodiments, the plasma-facing surfaces of different electrode segments may have different dimensions (such as width or surface area) or the same dimension. In one or more embodiments, the different electrode segments may have different spacing relative to one another or may be uniformly spaced.

In one or more embodiments, the electrode segments form substantially concentric rings. In one or more embodiments, the electrode segments are aligned in an array arrangement with either uniform or non-uniform spacings and with either repeating or non-repeating patterns or a combination thereof.

In one or more embodiments, local uniformity control in a plasma processing chamber utilizing a multi-segment upper electrode assembly with at least one electrode segment having a non-planar plasma-facing surface is tunable by varying, the gap between the upper electrode assembly and the substrate. In one or more embodiments, such tuning is performed prior to commencing substrate processing of a substrate. Alternatively or additionally, such tuning may be performed in-situ during processing in response to sensor measurements, in one or more embodiments.

In one or more embodiments, local uniformity control in a plasma processing chamber utilizing a multi-segment upper electrode assembly with at least one electrode segment having a non-planar plasma-facing surface is tunable, alternatively or additionally, by varying the degree of co-planarity of the plasma-facing surfaces (whether concave, convex, or planar) of different electrode segments. In one or more embodiments, such tuning is performed prior to commencing substrate processing of a substrate. Alternatively, such tuning may be performed in-situ during processing in response to sensor measurements, in one or more embodiments.

In one or more embodiments, the plasma-facing surface(s) of the multi-segment upper electrode assembly is formed from or coated with a material that is compatible with the contamination specification for the substrate being processed and also sufficiently robust to withstand or resist rapid erosion by the plasma. For example, materials such as Si or SiC or another suitable material may be employed for the plasma-facing surface. The body of the multi-segment upper electrode assembly may be formed using a metal such as aluminum for good RF and heat conduction, in one or more embodiments.

These and other features and advantages of embodiments of the invention may be better understood with reference to the figures and discussions that follow. It should be kept in mind that these examples are only illustrative and are not limiting of the scope of the invention.

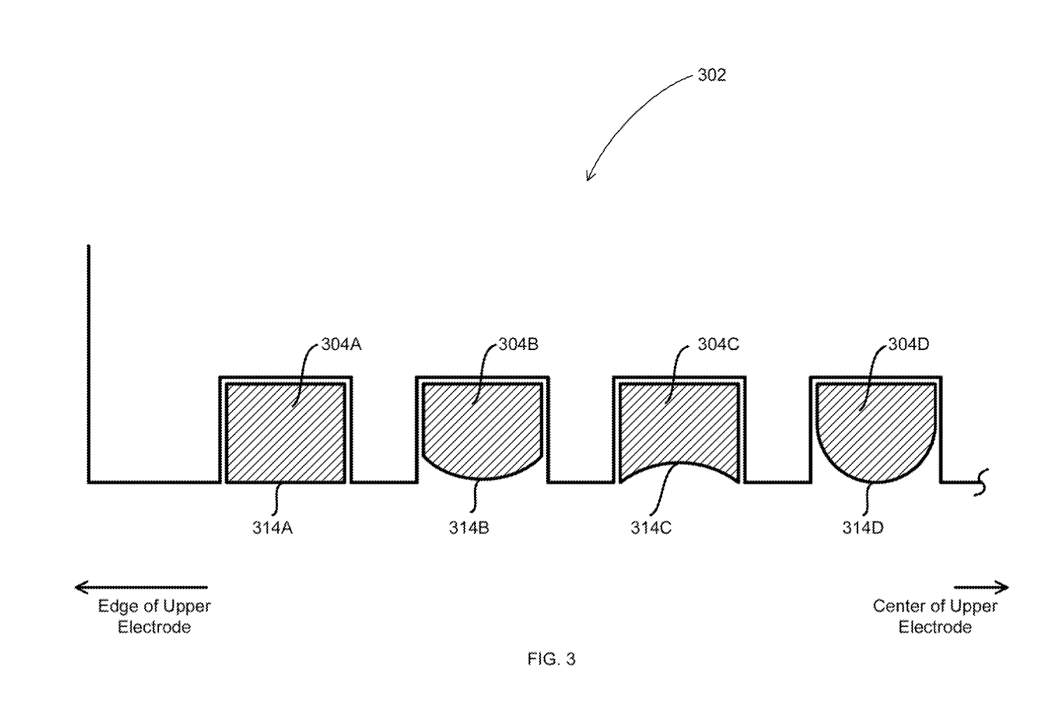

FIG. 3 shows, in accordance with an embodiment of the invention, the cross-section view of a multi-segment electrode 302 having four electrode segments 304A, 3048, 304C, and 304D. In the example of FIG. 3, multi-segment electrode 302 represents the upper electrode assembly, and each of electrode segments 304A, 304B, 304C, and 304D may be powered by a different RE power source. Generally speaking, the electrode segments are electrically insulated from one another in an RF sense using a suitable dielectric material disposed in between the electrode segments, for example.

Electrode segment 304A has a plasma-facing or substrate holder-facing surface 314A. Electrode segment 304B has a plasma-facing or substrate holder-facing surface 314B. Electrode segment 304C has a plasma-facing or substrate holder-facing surface 314C. Electrode segment 304D has a plasma-facing or substrate holder-facing surface 314D,

In the example of FIG. 3, plasma-facing surface 314A of electrode segment 304A is planar; plasma-facing surface 314B of electrode segment 304B is convex; plasma-facing surface 314C of electrode segment 304C is concave; and plasma-facing surface 314D of electrode segment 304D is convex again, albeit with a different degree of convexity relative to convex plasma-facing surface 314B of electrode segment 304B.

The example of FIG. 3 is intended to illustrate that different plasma-facing surfaces or substrate holder-facing surfaces of different electrode segments can have different surface profiles. It should be understood, however, that it's possible for all plasma-facing surfaces or substrate holder-facing surfaces to be all concave (with the same or different degrees of curvature), or all convex (with the same or different degrees of curvature) in one or more embodiments.

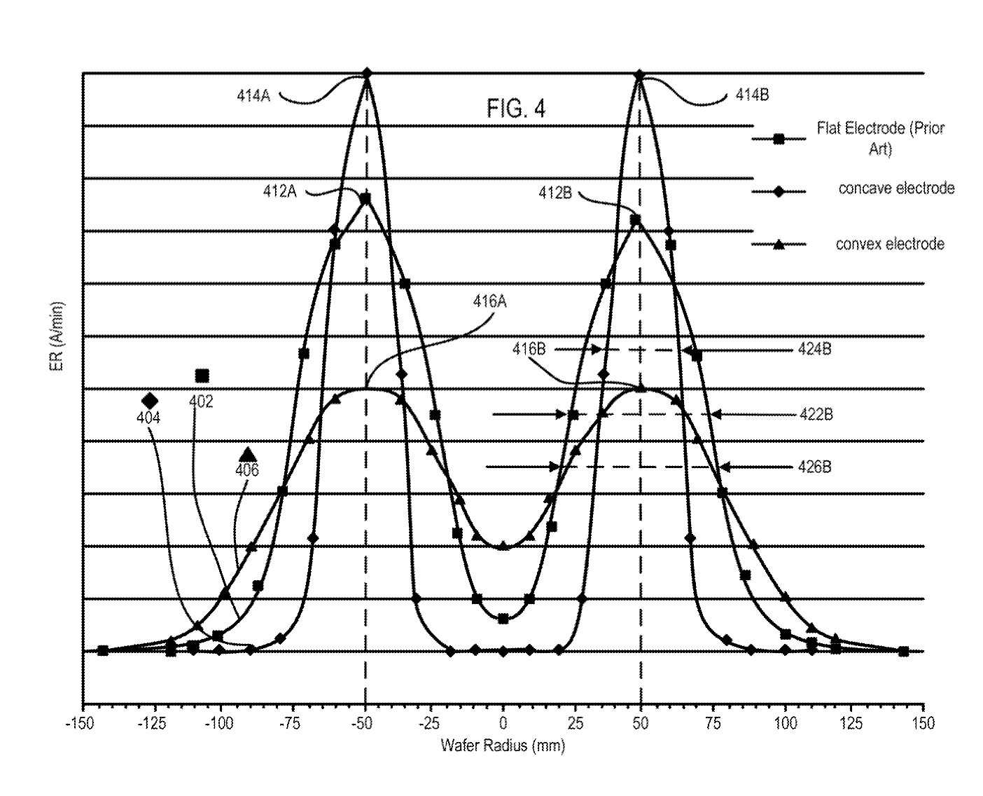

FIG. 4 conceptually shows the effect that the plasma-facing surface profile of a given concentric electrode segment (i.e., concentric around the center of the wafer) has on the etch rate across the wafer. Line 402 shows the etch rate for a concentric electrode segment having a flat plasma-facing surface. Note that there exist two peaks 412A and 412B (at about −50 mm and +50 mm from the wafer center) with full-width-at-half-maximum (FWHM) dimension 422B for peak 412B (and approximately the same FWHM dimension for peak 412A).

Line 404 shows the etch rate for a concentric electrode segment having a concave plasma-facing surface and disposed in the same radial location and having the same horizontal width as the electrode associated with line 402. Again, note that there exist two peaks 414A and 414B (at about −50 mm and +50 mm from the wafer center) with full-width-at-half-maximum (MUM) dimension 424B for peak 414B (and approximately the same FWHM dimension for peak 414A). Further, note that FWHM dimension 424B is substantially smaller than the MEM dimension 422B of the electrode segment having a flat plasma-facing surface. As can be seen in FIG. 3 and as reflected by the FWHM dimensions, the concave plasma-facing surface produces a much sharper localized effect at +50 mm and −50 mm positions when compared to the flat plasma-facing surface.

Line 406 shows the etch rate for a concentric electrode segment having a convex plasma-facing surface and disposed in the same radial location and having, the same horizontal width as the electrodes associated with lines 402 and 404. Again, note that there exist two peaks 416A and 416B (at about −50 mm and +50 mm from the wafer center) with full-width-at-half-maximum (FWHM) dimension 426B for peak 416B (and approximately the same FWHM dimension for peak 416A). Further, note that FWHM dimension 426B is substantially larger than the FWHM dimension 422B of the electrode segment having a flat plasma-facing surface. As can be seen in FIG. 3 and as reflected by the FWHM dimensions, the convex plasma-facing surface produces a much less sharp (i.e., more diffused) localized effect at about +50 mm and −50 mm positions when compared to the flat plasma-facing surface or the concave plasma-facing surface.

Although the result of FIG. 4 may not be observed or may not be as pronounced in all plasma chamber configurations, the specific result of FIG. 4 may be better appreciated using an optic analogy. A flat mirror tends to produce light in a particular pattern, while a concave mirror tends to focus the light to a particular spot (therefore resulting in a sharper localized effect). Contrarily, a convex mirror tends to disperse light in different directions, producing a much more diffused effect. However, as stated earlier, the specific effect produced by a shaped surface may vary in different chamber configurations. What remains true, however, is the fact that different surface profiles of different electrode segments influence the localized etch rates differently, and these differences may be exploited as a control knob to improve process uniformity in one or more embodiments.

The optic analogy may be employed to help explain (albeit as an imperfect analogy) other control knobs afforded by various embodiments of the invention. If the minor is non-planar (i.e., convex or concave), the light pattern changes as the distance from the mirror changes. In one or more embodiments, the gap between the multi-segment upper electrode (that has at least one shaped surface electrode segment) and the substrate may be changed in order to manipulate the localized effect exerted by the shaped plasma-facing surface(s) on the etch profile. This gap change may be made prior to plasma processing or may be made in-situ using an appropriate actuator in one or more embodiments. For example, the multi-segment upper electrode (that has at least one shaped surface electrode segment) may be employed in an adjustable gap plasma processing chamber of the type manufactured by Lam Research Corporation (Fremont, Calif.). In such an adjustable-gap plasma processing chamber, the gap between the wafer and the multi-segment upper electrode (that has at least one shaped surface electrode segment) may be changed either prior to plasma processing or in-situ as part of a recipe, for example. The adjustable-gap plasma processing chamber that employs prior art flat upper electrode may also be easily retrofitted to take advantage of the processing benefits offered by embodiments of the invention by simply swapping out the prior art flat upper electrode assembly and swapping in the disclosed multi-segment upper electrode (that has at least one shaped surface electrode segment).

Alternatively or additionally, in one or more embodiments, the degree of curvature of different shaped plasma-facing surfaces may be varied to achieve different localized process rate effects. Alternatively or additionally, in one or more embodiments, the degree of relative co-planarity (or lack thereof) among electrode segments (the plasma-facing surfaces of which may be non-planar or planar) may be varied to achieve different localized process rate effects. The degree of co-planarity may be achieved by using different electrode segments having different thicknesses, or by employing shims or spacers or spacer rings to make an electrode segment protrude more or less toward the plasma. The degree of co-planarity may also be achieved in-situ if actuators are employed to move the various electrode segments, for example.

Alternatively or additionally, the curved plasma-facing surface of one or more electrode segments may be angled much in the same manner that the optical axis of a mirror may be angled to cast a different light pattern on a surface. As mentioned, the different electrode segments may have the same or different widths, or the same or different surface areas. Further, the different electrode segments may be uniformly spaced relative to one another or non-uniformily spaced. These are all additional control knobs to afford the process engineer more localized control over process uniformity.

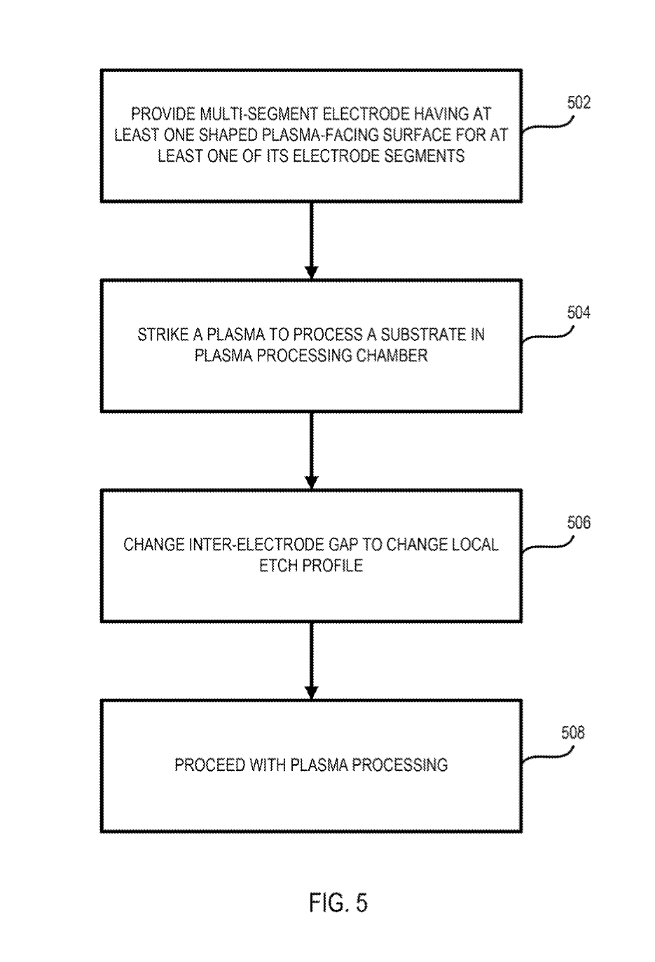

FIG. 5 shows, in accordance with an embodiment of the invention, the steps for tuning process uniformity using the inventive multi-segment electrode having at least one shaped plasma facing surface for at least one of its electrode segments. In step 502, a plasma processing chamber equipped with a multi-segment electrode having at least one shaped plasma-facing surface for at least one of its electrode segments is provided. In the example of FIG. 5, the multi-segment electrode is employed as the upper electrode assembly although this is not a limitation of the invention.

In step 504, a plasma is struck and sustained to process a substrate in the plasma processing chamber.

In step 506, the gap between the upper electrode assembly and the substrate is adjusted to tune the localized etch rates at different locations on the substrate. Step 506 may occur before or after step 504, depending on etching needs. The gap dimension may be determined in advance, or may be determined on-the-fly in response to sensor measurements in one or more embodiments. In step 508, plasma processing proceeds.

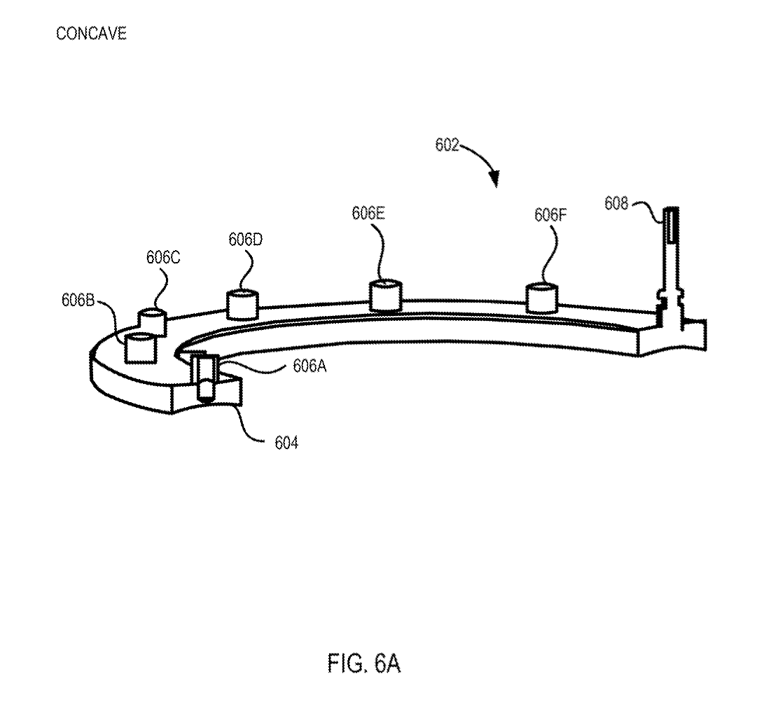

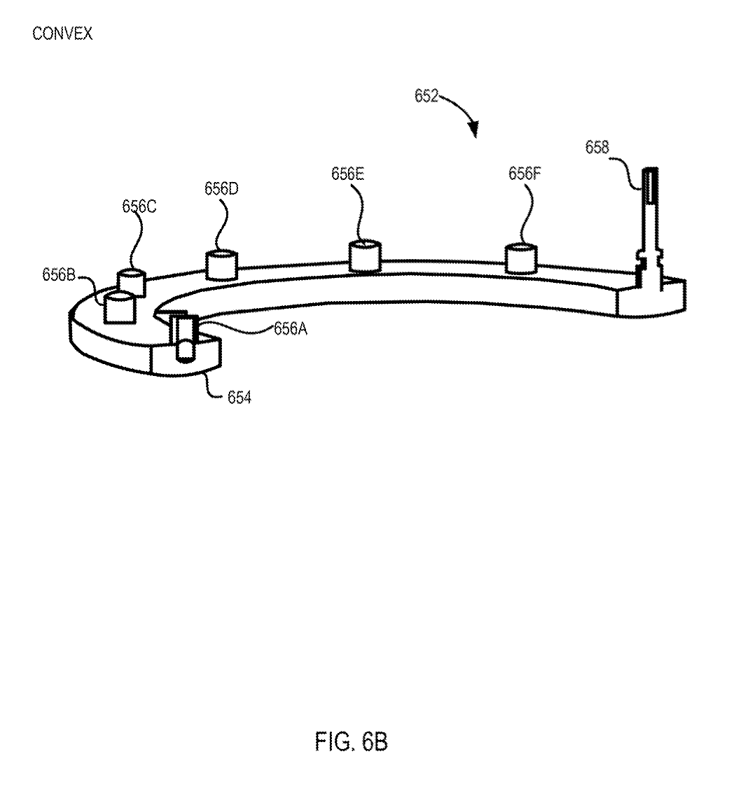

FIG. 6A shows, in accordance with an embodiment, a portion of a concentric ring electrode segment 602 having a concave plasma-facing surface 604. Mounting shafts 606A-606F for mounting (using for example stainless bolts) electrode segment 602 to the remaining of the upper electrode assembly are shown, along with RF feed rod 608. Electrode segment 602 represents a readily-swappable plasma-facing portion of the upper electrode assembly and may be swapped for another electrode segment having a different plasma-facing surface profile to realize a different localized etch rate effect. In this manner, it is unnecessary to replace the entire top end or even all of the electrode segments of a top end when a change in localized control of the etch profile is desired.

FIG. 6B shows, in accordance with an embodiment, a portion of a concentric ring electrode segment 652 having a convex plasma-facing surface 654. Mounting shafts 656A-656F for mounting (using for example stainless bolts) electrode segment 652 to the remaining of the upper electrode assembly are shown, along with RF feed rod 658. Electrode segment 652 also represents a readily-swappable plasma-facing portion of the upper electrode assembly and may be swapped for another electrode segment having a different plasma-facing surface profile to realize a different localized etch rate effect.

As can he appreciated from the foregoing, embodiments of the invention provide additional control knobs to enable the process engineer to tune local etch rates and to exert localized control on the etch profile across the wafer. For example, the etch profile may be changed by changing, the gap between the upper electrode and the lower electrode in the manner discussed above. As another example, the etch profile may be changed h swapping out the plasma-facing portion of the upper electrode assembly in order to employ one with a different set of shaped plasma-facing surfaces, for example. This is substantially simpler and less expensive than swapping out the entire chamber top end to obtain a change in the uniformity profile (as has been done in the prior art).

While this invention has been described in terms of several. preferred embodiments, there are alterations, permutations, and equivalents, which fall within the scope of this invention. If the term “set” is employed herein, such term is intended to have its commonly understood mathematical meaning to cover zero, one, or more than one member. The invention should he understood to also encompass these alterations, permutations, and equivalents. It should also be noted that there are many alternative ways of implementing the methods and apparatuses of the present invention. Although various examples are provided herein, it is intended that these examples be illustrative and not limiting with respect to the invention.

What is claimed is:

1. A multi-segment electrode assembly having a plurality of electrode segments for modifying a plasma in a plasma processing chamber, comprising:
a first powered electrode segment having a first plasma-facing surface, said first powered electrode segment configured to be powered by a first RF signal; and
a second powered electrode segment having a second plasma-facing surface, said second powered electrode segment configured to be powered by a second RE signal, said second powered electrode segment being electrically insulated from said first powered electrode segment, at least one of said first plasma-facing surface and said second plasma-facing surface is non-planar.

2. The multi-segment electrode assembly of claim 1 wherein one of said first plasma-facing surface and said second plasma-facing surface includes at least a convex surface portion.

3. The multi-segment electrode assembly of claim 2 wherein the other of said first plasma-facing surface and said second plasma-facing surface includes at least a concave surface portion.

4. The multi-segment electrode assembly of claim 2 wherein the other of said first plasma-facing surface and said second plasma-facing surface is planar.

5. The multi-segment electrode assembly of claim 1 wherein one of said first plasma-facing surface and said second plasma-facing surface includes at least a concave surface portion.

6. The multi-segment electrode assembly of claim 5 wherein the other of said first plasma-facing surface and said second plasma-facing surface is planar.

7. The multi-segment electrode assembly of claim 1 wherein said first powered electrode segment and said second powered electrode segment are concentric relative to one another.

8. The multi-segment electrode assembly of claim 1 wherein said first plasma facing surface and said second plasma facing surface are both opposite a plasma-facing surface. of a substrate when said substrate is disposed in said plasma processing chamber for processing.

9. The multi-segment electrode assembly of claim 1 wherein said plasma processing chamber represents an adjustable-gap plasma processing chamber wherein a gap between said substrate and said multi-segment electrode assembly is adjustable.

10. The multi-segment electrode assembly of claim 1 wherein said gap between said substrate and said multi-segment electrode assembly is adjustable in-situ.

11. A plasma processing system having at least a plasma processing chamber for processing a substrate, comprising:
a substrate holder configured for supporting said substrate during said processing;
a multi-segment electrode assembly disposed in a spaced-apart manner opposite said substrate holder, wherein a plasma generating volume exists in a gap between said multi-segment electrode and said substrate during said processing, said multi-segment electrode assembly including
a first powered electrode segment having a first substrate holder-facing surface, said first powered electrode segment configured to be powered by a first RF signal, and
a second powered electrode segment having a second substrate holder-facing surface, said second powered electrode segment configured to be powered by a second RF signal, said second powered electrode segment being electrically insulated from said first powered electrode segment, at least one of said first substrate holder-facing surface and said second substrate holder-facing surface is non-planar.

12. The plasma processing system of claim 11 wherein one of said first substrate holder-facing surface and said second substrate holder-facing surface includes at least a convex surface portion.

13. The plasma processing system of claim 12 wherein the other of said first substrate holder-facing surface and said second substrate holder-facing surface includes at least a concave surface portion.

14. The plasma processing system of claim 12 wherein the other of said first substrate holder-facing surface and said second substrate holder-facing surface is planar.

15. The plasma processing system of claim 11 wherein one of said first substrate holder-facing surface and said second substrate holder-facing surface includes at least a concave surface portion.

16. The plasma processing system of claim 15 wherein the other of said first substrate holder-facing surface and said second substrate holder-facing surface is planar.

17. The plasma processing system of claim 11 wherein said first powered electrode segment and said second powered electrode segment are concentric relative to one another.

18. The plasma processing system of claim 11 wherein said gap is adjustable.

19. The plasma processing system of claim 11 wherein said gap is adjustable in-situ.

20. The plasma processing system of claim 11 wherein said first powered electrode segment and said second powered electrode segment are not co-planar relative to one another.

21. The plasma processing system of claim 11 wherein said first powered electrode segment and said second powered electrode segment are co-planar relative to one another.
